(19) United States
(12) Patent Application Publication
(10) Pub. No.: US 2026/0231793 A1
(43) Pub. Date: Aug. 6, 2026

(54) PACKAGE MODULE AND MANUFACTURING METHOD THEREOF

(71) Applicant: SILICONWARE PRECISION INDUSTRIES CO., LTD., Taichung City (TW)

(72) Inventors: Yun-Hong LIU, Taichung City (TW); Feng KAO, Taichung City (TW); Jui-Cheng LIN, Taichung City (TW); Yen-Chu KO, Taichung City (TW); Wen-Jung TSAI, Taichung City (TW)

(73) Assignee: SILICONWARE PRECISION INDUSTRIES CO., LTD., Taichung City (TW)

(21) Appl. No.: 19/440,588

(22) Filed: Jan. 5, 2026

(30) Foreign Application Priority Data
Feb. 3, 2025 (TW) 114103862

(51) Int. Cl. H10W 70/60; H10W 70/06; H10W 70/63; H10W 74/15; H10W 90/00; H10W 90/10

(52) U.S. Cl. CPC H10W 70/618; H10W 70/06; H10W 70/635; H10W 90/10; H10W 74/15; H10W 90/724

(57) ABSTRACT

A package module and a manufacturing method thereof are provided, in which a circuit structure is formed on a carrier board, a plurality of electronic components are disposed on and electrically connected to the circuit structure, and a reinforcement member is disposed on the plurality of electronic components. Then, the carrier board is removed, the reinforcement member is disposed on a temporary carrier, and a singulation process is performed. Therefore, the structural strength of the package module is enhanced by the reinforcement member, thereby preventing the occurrence of warpage problems.

### BACKGROUND

### 1. Technical Field

The present disclosure relates to a semiconductor packaging technology, and more particularly, to a package module including a plurality of package units and a manufacturing method thereof.

2. Description of Related Art

Applications (such as the development of medical technology, the development of cancer drugs, or the automatic sensing and detection computing of self-driving cars) of high performance computing (HPC) technology in nowadays life is becoming more and more important and widespread. Among them, package structures used by equipment applied in these fields are mostly fan-out package (FOPKG) structures. For example, fan-out multi-chip module (FOMCM) structures and fan-out embedded bridge (FOEB) die structures have the requirements of multi-chip/high number of circuit layers/large fan-out size/high heat dissipation design.

FIG. 1 shows a conventional fan-out package structure, in which a chip 11 is buried in an encapsulation layer 15, a redistribution layer (RDL) 10 is then formed on the encapsulation layer 15, and then functional chips 16 are disposed on the redistribution layer 10. In this way, the functional chips 16 and the chip 11 embedded in the encapsulation layer 15 can communicate vertically to meet the high-speed transmission requirements.

However, when the package structure is very thin and has a very large planar dimension (e.g., the thickness of the package structure is less than 300 μm and the planar dimension of the package structure is greater than 70×70 mm-100×100 mm) so as to meet the development trend of electronic products having multi-function and being light, thin, short and compact, it is prone to increase the difficulty of the wafer-based manufacturing process and have a high risk of warping and deformation when the package structure is subsequently connected to a circuit board.

Therefore, how to overcome the aforementioned problems of the prior art has become an urgent issue to be solved.

### SUMMARY

In view of the aforementioned shortcomings of the prior art, the present disclosure provides a package module (which is of a monolithic structure) comprising a plurality of package units disposed on a temporary carrier, each of the plurality of package units comprises: a reinforcement member disposed on the temporary carrier; a plurality of electronic components disposed on the reinforcement member; and a circuit structure formed on and electrically connected to the plurality of electronic components.

The present disclosure further provides a method of manufacturing a package module (which is of a monolithic structure) comprising a plurality of package areas, the method comprises: forming a circuit structure on a carrier board; disposing a plurality of electronic components on the circuit structure, wherein the plurality of electronic components are electrically connected to the circuit structure; disposing a reinforcement member on the plurality of electronic components; removing the carrier board; disposing the reinforcement member on a temporary carrier; and performing a singulation process along each of the plurality of package areas to form a plurality of package units.

In the aforementioned package module and method, the present disclosure further comprises a plurality of conductive pillars disposed on and electrically connected to the circuit structure.

In the aforementioned package module and method, the present disclosure further comprises a plurality of bridge chips disposed on and electrically connected to the circuit structure.

In the aforementioned package module and method, the present disclosure further comprises an encapsulation layer formed on the circuit structure and encapsulating the plurality of bridge chips and the plurality of conductive pillars.

In the aforementioned package module and method, the present disclosure further comprises a circuit portion disposed on the encapsulation layer, wherein the circuit portion is electrically connected to the plurality of conductive pillars.

In the aforementioned package module and method, the present disclosure further comprises a plurality of conductive components disposed on and electrically connected to the circuit portion.

In the aforementioned package module and method, the present disclosure further comprises a plurality of conductive components disposed on and electrically connected to the circuit structure.

In the aforementioned package module and method, the present disclosure further comprises a packaging layer formed on the circuit structure and encapsulating the plurality of electronic components.

In the aforementioned package module and method, each of the plurality of package units is of a fan-out embedded bridge structure or a fan-out multi-chip structure.

It can be seen from the above that, in the package module (which is of a monolithic structure) and manufacturing method thereof of the present disclosure, the reinforcement member is disposed on the plurality of electronic components of the plurality of package units to enhance the overall structural strength and mitigate the warpage issue. Meanwhile, when each of the package units is subsequently connected to an external device, the warpage phenomenon can be controlled through the arrangement of the reinforcement member.

### BRIEF DESCRIPTION OF THE DRAWINGS

FIG. 1 is a schematic cross-sectional view showing a conventional fan-out package structure.

FIG. 2A to FIG. 2G are schematic cross-sectional views illustrating a method of manufacturing a package module of a first embodiment of the present disclosure.

FIG. 3 is a schematic cross-sectional view showing an application of the package module of the first embodiment of the present disclosure.

FIG. 4A to FIG. 4D are schematic cross-sectional views illustrating a method of manufacturing a package module of a second embodiment of the present disclosure.

FIG. 5 is a schematic cross-sectional view showing an application of the package module of the second embodiment of the present disclosure.

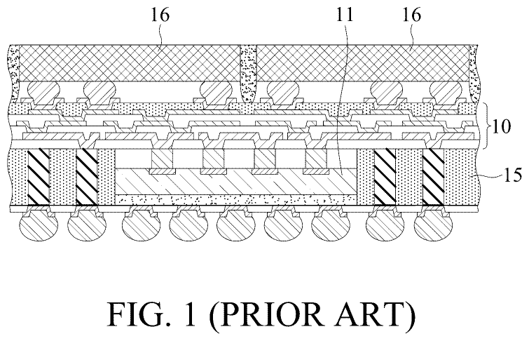

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

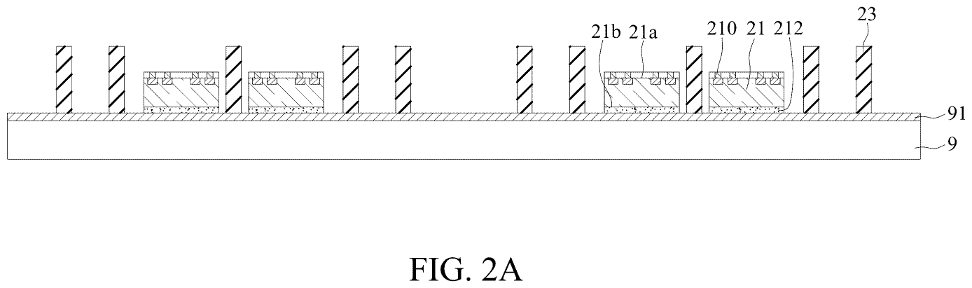

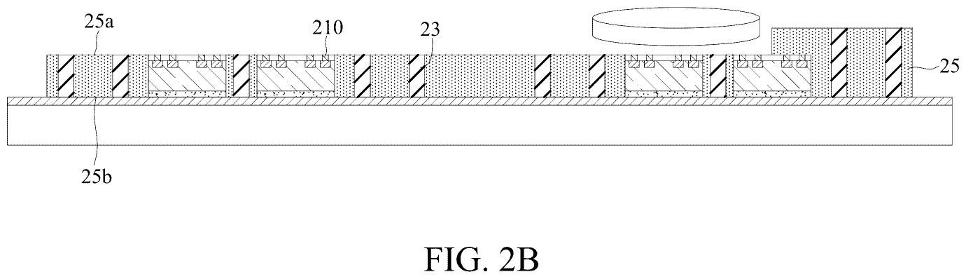

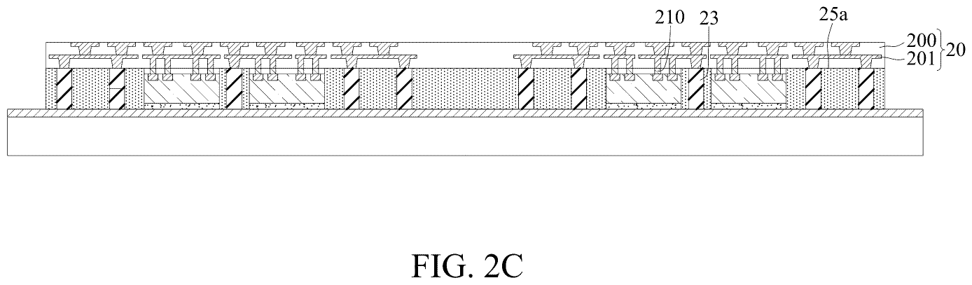

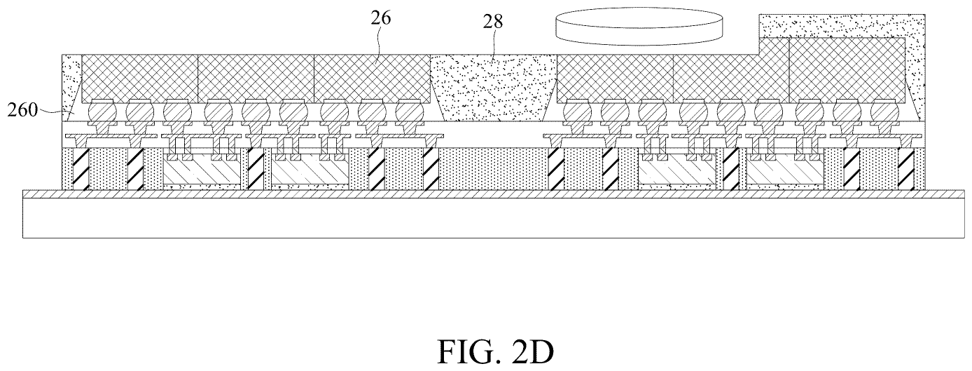

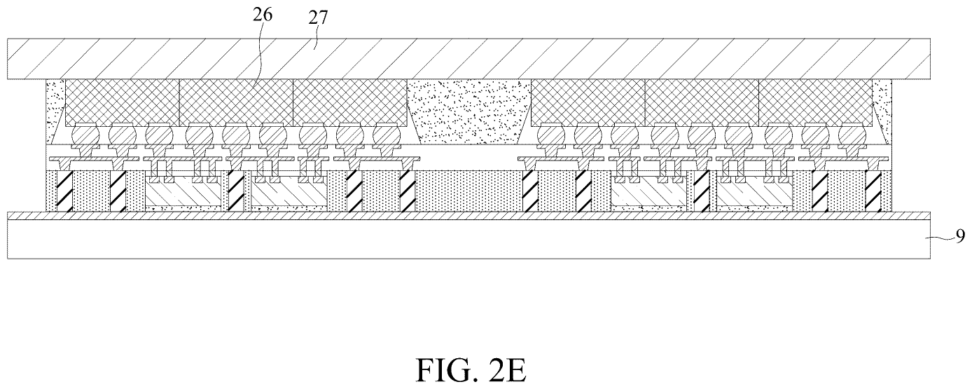

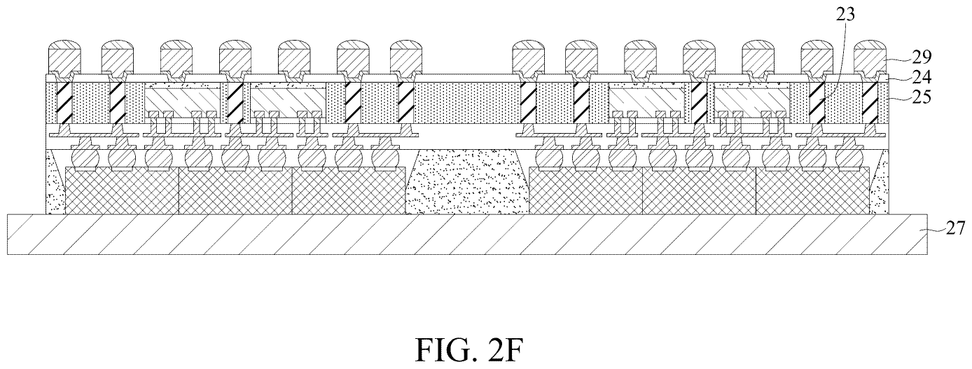

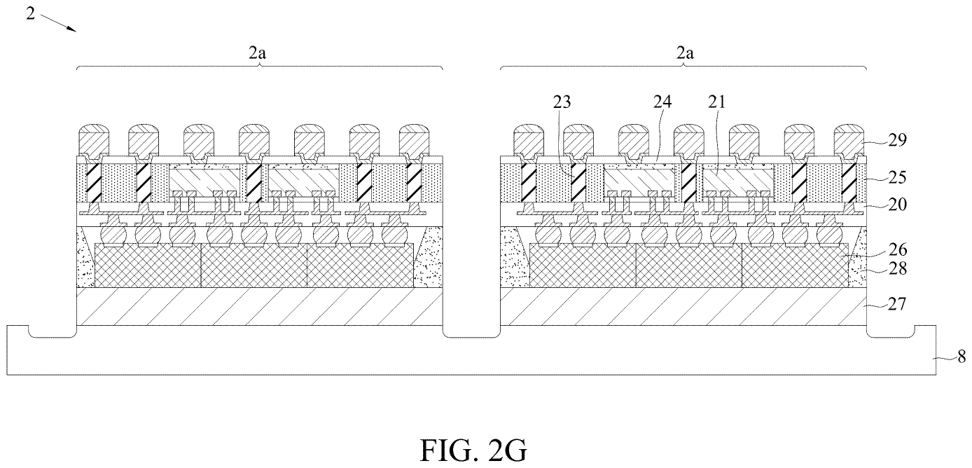

FIG. 2A to FIG. 2G are schematic cross-sectional views illustrating a method of manufacturing a package module 2 of a first embodiment of the present disclosure. The package module 2 of the present disclosure is of a monolithic structure in a wafer form or a panel form, and the package module 2 includes a plurality of package areas.

As shown in FIG. 2A, a carrier board 9 is provided, a plurality of conductive pillars 23 are formed on the carrier board 9, and a plurality of bridge chips 21 are disposed on the carrier board 9.

In an embodiment, a release layer, an insulating layer 91 made of such as dielectric material or solder-resist material, and a seed layer made of such as titanium/copper can be formed on the carrier board 9 in sequence, such that the seed layer is formed on the insulating layer 91, and a patterned resist layer is formed on the seed layer to form the plurality of conductive pillars 23, wherein the conductive pillars 23 are made of metal material such as copper or made of solder material. After the plurality of conductive pillars 23 are formed, the patterned resist layer and the seed layer therebelow are removed, and the plurality of bridge chips 21 are disposed on the carrier board 9, such that the bridge chips 21 are surrounded by the plurality of conductive pillars 23, wherein each of the bridge chips 21 is bonded and electrically connected to a plurality of conductors 210, and the plurality of conductors 210 are spherical conductive members such as solder balls, pillar-shaped metal conductive members such as copper posts, solder bumps, etc., or stud-shaped conductive members made by a wire bonding machine, but the present disclosure is not limited to as such.

Moreover, the bridge chip 21 has an active surface 21a and an inactive surface 21b opposite to the active surface 21a, wherein the inactive surface 21b of the bridge chip 21 is adhered to the insulating layer 91 via a bonding layer 212, the active surface 21a of the bridge chip 21 has a plurality of electrode pads and a protective film made of such as passivation material, and the conductors 210 are disposed on the electrode pads respectively and embedded in the protective film.

As shown in FIG. 2B, an encapsulation layer 25 is formed on the insulating layer 91 of the carrier board 9, such that the encapsulation layer 25 encapsulates the bridge chips 21, the plurality of conductors 210 and the plurality of conductive pillars 23, wherein the encapsulation layer 25 has a first surface 25a and a second surface 25b opposite to the first surface 25a, and the second surface 25b of the encapsulation layer 25 is bonded to the insulating layer 91 of the carrier board 9. In an embodiment, the encapsulation layer 25 is made of insulating material such as polyimide (PI), dry film, epoxy molding colloid, or epoxy molding compound.

Furthermore, a leveling process is performed, so that the first surface 25a of the encapsulation layer 25 is flush with end surfaces of the plurality of conductive pillars 23 and end surfaces of the plurality of conductors 210, such that the end surfaces of the plurality of conductive pillars 23 and the end surfaces of the plurality of conductors 210 are exposed from the first surface 25a of the encapsulation layer 25.

As shown in FIG. 2C, a circuit structure 20 is formed on the first surface 25a of the encapsulation layer 25, and the circuit structure 20 is electrically connected to the plurality of conductive pillars 23 and the plurality of conductors 210.

In an embodiment, the circuit structure 20 comprises a plurality of dielectric layers 200 and a plurality of redistribution layers (RDLs) 201 formed on the dielectric layers 200. Alternatively, the circuit structure 20 can also comprise only a single dielectric layer 200 and a single redistribution layer 201.

In addition, the redistribution layer 201 is made of copper, and the dielectric layer 200 is made of polybenzoxazole (PBO), polyimide (PI), prepreg (PP), or other dielectric materials.

As shown in FIG. 2D, a plurality of electronic components 26 are disposed on the circuit structure 20, and a packaging layer 28 is formed and encapsulates the plurality of electronic components 26.

In an embodiment, each of the electronic components 26 can be an active component, a passive component, or a combination of the active component and the passive component. In one implementation, each of the electronic components 26 is, for example, a semiconductor chip such as a graphics processing unit (GPU), a high bandwidth memory (HBM), etc.

Additionally, the electronic components 26 are electrically connected to the circuit structure 20 via a plurality of conductive bumps such as solder bumps, copper bumps, or others, and at least two of the electronic components 26 can be electrically connected to each other via the bridge chip 21.

Moreover, the packaging layer 28 is made of insulating material such as polyimide (PI), dry film, epoxy molding colloid, or epoxy molding compound, and the packaging layer 28 can be formed on the circuit structure 20 by lamination or molding. It should be understood that the material for forming the packaging layer 28 can be the same as or different from the material for forming the encapsulation layer 25.

Furthermore, an underfill 260 can also be firstly formed between the electronic components 26 and the circuit structure 20 to encapsulate the plurality of conductive bumps, and then the packaging layer 28 is formed to encapsulate the underfill 260 and the plurality of electronic components 26. The underfill 260 can be selectively formed or not formed between the electronic components 26 and the circuit structure 20.

In addition, a thinning process is performed, so that a portion of material of the packaging layer 28 and a portion of material of each of the plurality of electronic components 26 are removed, and an upper surface of the packaging layer 28 is flush with upper surfaces of the plurality of electronic components 26, such that the plurality of electronic components 26 are exposed from the packaging layer 28.

As shown in FIG. 2E, a reinforcement member 27 is disposed on the plurality of electronic components 26. The reinforcement member 27 is, for example, a plate made of semiconductor material (such as silicon or glass).

As shown in FIG. 2F, the carrier board 9 and the release layer and metal layer thereon are then removed, and a circuit portion 24 is formed on the encapsulation layer 25 and electrically connected to the plurality of conductive pillars 23. The circuit portion 24 can further include an insulating layer 91 and an under bump metallization (UBM) layer so as to be bonded to a plurality of conductive components 29 such as solder bumps or solder balls (which are of controlled collapse chip connection [C4] specification); alternatively, the circuit portion 24 can be formed on the encapsulation layer 25 by an RDL process so as to be bonded to the conductive components 29.

As shown in FIG. 2G, after the reinforcement member 27 is disposed on a temporary carrier 8, a singulation process is performed along each of the package areas to obtain the package module 2 including a plurality of package units 2a. The temporary carrier 8 is an adhesive carrier member, such as a tape.

Through the aforementioned manufacturing method, the present disclosure provides a package module 2, which is of a monolithic structure, and the package module 2 includes a plurality of package units 2a disposed on a temporary carrier 8, wherein each of the package units 2a comprises: a reinforcement member 27 disposed on the temporary carrier 8; a plurality of electronic components 26 disposed on the reinforcement member 27; and a circuit structure 20 formed on the plurality of electronic components 26, wherein the plurality of electronic components 26 are electrically connected to the circuit structure 20.

In an embodiment, each of the package units 2a is of, for example, a fan-out embedded bridge (FOEB) structure, and each of the package units 2a further includes an encapsulation layer 25 formed on the circuit structure 20, a plurality of conductive pillars 23 and a plurality of bridge chips 21 embedded in the encapsulation layer 25, a circuit portion 24 disposed on the encapsulation layer 25, and a plurality of conductive components 29 disposed on the circuit portion 24.

The plurality of bridge chips 21 and the plurality of conductive pillars 23 are electrically connected to the circuit structure 20. The plurality of conductive pillars 23 are embedded in the encapsulation layer 25 and surround the bridge chips 21. The circuit portion 24 is electrically connected to the plurality of conductive pillars 23 and the plurality of conductive components 29.

In an embodiment, each of the package units 2a further includes a packaging layer 28 formed on the circuit structure 20 and encapsulating the plurality of electronic components 26.

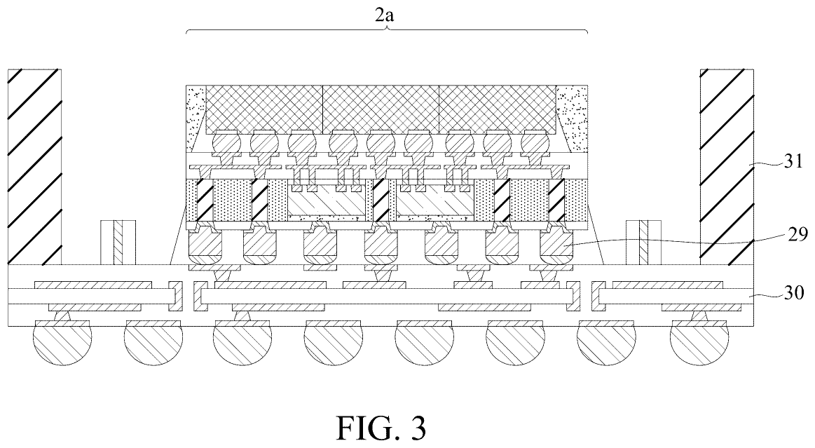

Please refer to FIG. 3, each of the package units 2a is subsequently connected to an external device 30 (such as a circuit board) via the plurality of conductive components 29, then the reinforcement member 27 is removed, and a heat sink 31 is disposed on the external device 30.

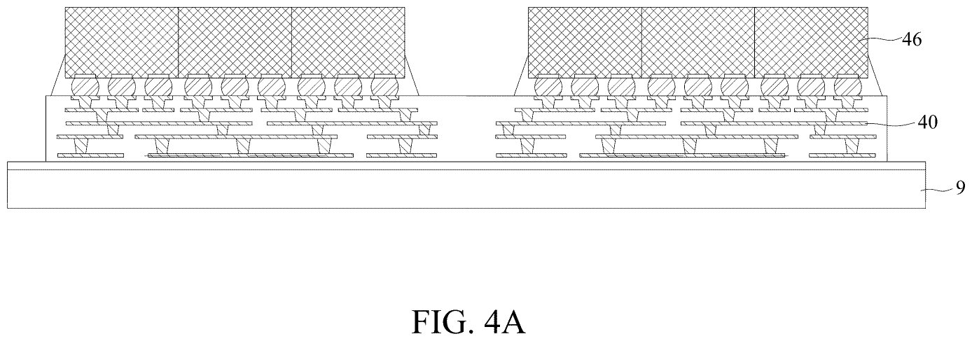

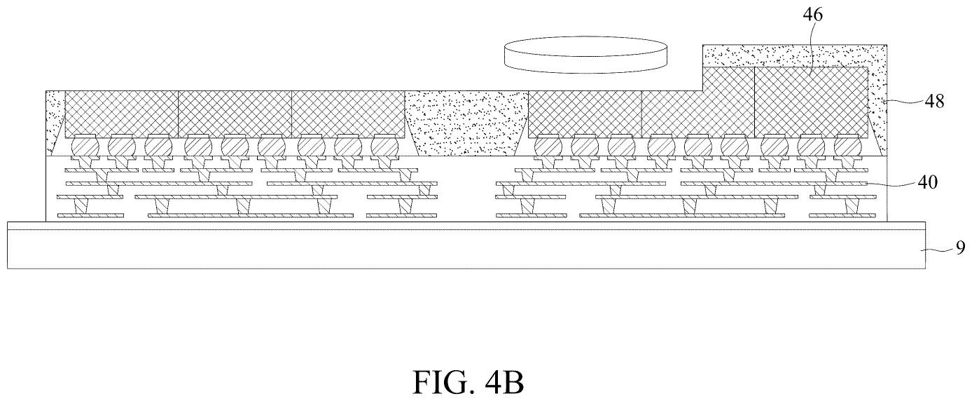

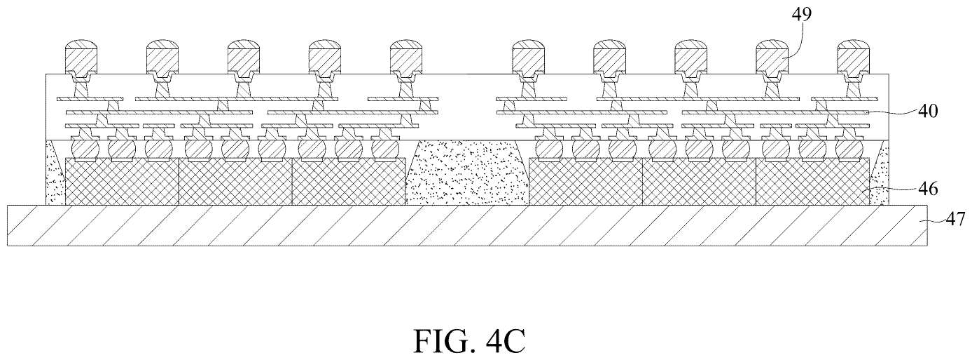

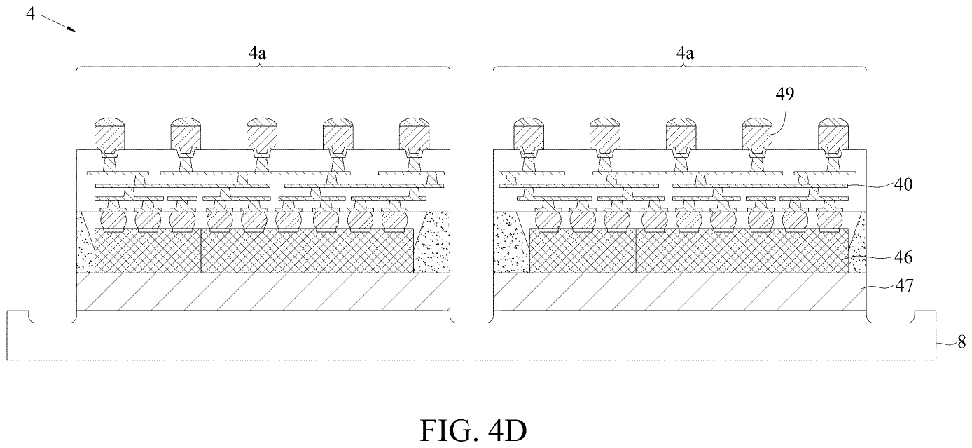

FIG. 4A to FIG. 4D are schematic cross-sectional views illustrating a method of manufacturing a package module 4 of a second embodiment of the present disclosure. The package module 4 of the present disclosure is of a monolithic structure in a wafer form or a panel form, and the package module 4 includes a plurality of package areas.

As shown in FIG. 4A, a carrier board 9 is provided, and a circuit structure 40 is formed on the carrier board 9, then a plurality of electronic components 46 are disposed on the circuit structure 40. The circuit structure 40 comprises a plurality of dielectric layers and a plurality of redistribution layers, and each of the electronic components 46 can be an active component, a passive component, or a combination of the active component and the passive component.

As shown in FIG. 4B, a packaging layer 48 is formed on the circuit structure 40 to encapsulate the plurality of electronic components 46, and a thinning process is performed to remove a portion of material of the packaging layer 48 and a portion of material of each of the plurality of electronic components 46, so that an upper surface of the packaging layer 48 is flush with upper surfaces of the plurality of electronic components 46, such that the plurality of electronic components 46 are exposed from the packaging layer 48.

As shown in FIG. 4C, a reinforcement member 47 is disposed on the plurality of electronic components 46. The reinforcement member 47 is, for example, a plate made of semiconductor material (such as silicon or glass). The carrier board 9 is removed to expose the circuit structure 40, and then a plurality of conductive components 49 are disposed on the circuit structure 40.

As shown in FIG. 4D, after the reinforcement member 47 is disposed on a temporary carrier 8, a singulation process is performed along each of the package areas to obtain the package module 4 including a plurality of package units 4a.

Through the aforementioned manufacturing method, the present disclosure provides a package module 4, which is of a monolithic structure, and the package module 4 includes a plurality of package units 4a disposed on a temporary carrier 8, wherein each of the package units 4a comprises: a reinforcement member 47 disposed on the temporary carrier 8; a plurality of electronic components 46 disposed on the reinforcement member 47; and a circuit structure 40 formed on the plurality of electronic components 46, wherein the plurality of electronic components 46 are electrically connected to the circuit structure 40.

In an embodiment, each of the package units 4a is of, for example, a fan-out multi-chip module (FOMCM) structure, wherein each of the package units 4a further includes a plurality of conductive components 49 disposed on the circuit structure 40, and a packaging layer 48 encapsulating the plurality of electronic components 46, wherein the plurality of conductive components 49 are electrically connected to the circuit structure 40.

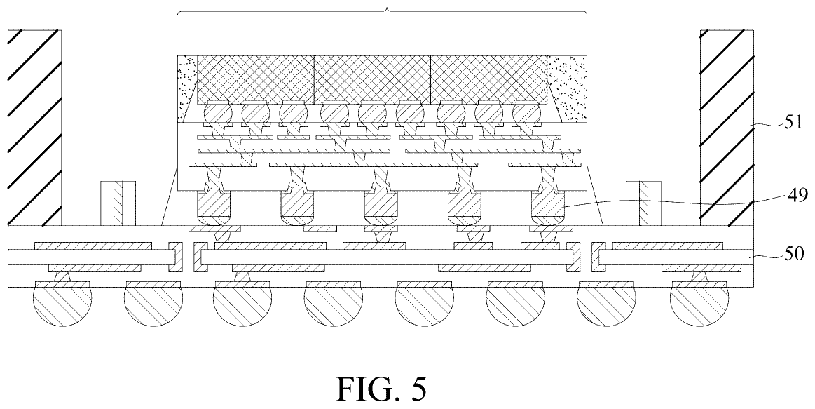

Please refer to FIG. 5, each of the package units 4a is subsequently connected to an external device 50 (such as a circuit board) via the plurality of conductive components 49, then the reinforcement member 47 is removed, and a heat sink 51 is disposed on the external device 50.

To sum up, in the package module (which is of a monolithic structure) and manufacturing method thereof of the present disclosure, the reinforcement member is disposed on the plurality of electronic components of the plurality of package units to enhance the overall structural strength and mitigate the warpage issue. Meanwhile, when each of the package units is subsequently connected to an external device, the warpage phenomenon can be controlled through the arrangement of the reinforcement member. Additionally, existing materials, processes and machines can be used to make the package module, so there is no need to develop new materials and processes or purchase new machines for making the package module, thereby solving the industry's existing problems without incurring a large amount of cost.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package module comprising a plurality of package units disposed on a temporary carrier, each of the plurality of package units comprising:
a reinforcement member disposed on the temporary carrier;
a plurality of electronic components disposed on the reinforcement member; and
a circuit structure formed on and electrically connected to the plurality of electronic components.

2. The package module of claim 1, further comprising: a plurality of conductive pillars disposed on and electrically connected to the circuit structure.

3. The package module of claim 2, further comprising: a plurality of bridge chips disposed on and electrically connected to the circuit structure.

4. The package module of claim 3, further comprising: an encapsulation layer formed on the circuit structure and encapsulating the plurality of bridge chips and the plurality of conductive pillars.

5. The package module of claim 4, further comprising: a circuit portion disposed on the encapsulation layer, wherein the circuit portion is electrically connected to the plurality of conductive pillars.

6. The package module of claim 5, further comprising: a plurality of conductive components disposed on and electrically connected to the circuit portion.

7. The package module of claim 1, further comprising: a plurality of conductive components disposed on and electrically connected to the circuit structure.

8. The package module of claim 1, further comprising: a packaging layer formed on the circuit structure and encapsulating the plurality of electronic components.

9. The package module of claim 1, wherein each of the plurality of package units is of a fan-out embedded bridge structure or a fan-out multi-chip structure.

10. A method of manufacturing a package module comprising a plurality of package areas, the method comprising:
forming a circuit structure on a carrier board;
disposing a plurality of electronic components on the circuit structure, wherein the plurality of electronic components are electrically connected to the circuit structure;
disposing a reinforcement member on the plurality of electronic components;
removing the carrier board;
disposing the reinforcement member on a temporary carrier; and
performing a singulation process along each of the plurality of package areas to form a plurality of package units.

11. The method of claim 10, further comprising: forming a plurality of conductive pillars between the carrier board and the circuit structure.

12. The method of claim 11, further comprising: disposing a plurality of bridge chips between the carrier board and the circuit structure.

13. The method of claim 12, further comprising: forming an encapsulation layer between the carrier board and the circuit structure to encapsulate the plurality of bridge chips and the plurality of conductive pillars, wherein the circuit structure is electrically connected to the plurality of bridge chips and the plurality of conductive pillars.

14. The method of claim 13, further comprising: after removing the carrier board, forming a circuit portion on the encapsulation layer, wherein the circuit portion is electrically connected to the plurality of conductive pillars.

15. The method of claim 14, further comprising: disposing a plurality of conductive components on the circuit portion, wherein the plurality of conductive components are electrically connected to the circuit portion.

16. The method of claim 10, further comprising: after removing the carrier board, disposing a plurality of conductive components on the circuit structure, wherein the plurality of conductive components are electrically connected to the circuit structure.

17. The method of claim 10, further comprising: forming a packaging layer on the circuit structure to encapsulate the plurality of electronic components.

18. The method of claim 10, wherein each of the plurality of package units is of a fan-out embedded bridge structure or a fan-out multi-chip structure.

19. The method of claim 10, further comprising: removing the reinforcement member disposed on each of the plurality of package units when each of the plurality of package units is connected to an external device.
